(19) United States
(12) Patent Application Publication
(10) Pub. No.: US 2016/0079100 A1
(43) Pub. Date: Mar. 17, 2016

(54) VACUUM CARRIER INTERFACE HAVING A SWITCHABLE REDUCED CAPACITY AIRLOCK CHAMBER

(71) Applicant: Lam Research Corporation, Fremont, CA (US)

(72) Inventor: Richard H. Gould, Fremont, CA (US)

(73) Assignee: Lam Research Corporation

(21) Appl. No.: 14/489,062

(22) Filed: Sep. 17, 2014

(51) Int. Cl. H01L 21/67; H01L 21/677; B25J 11/00; C23C 16/458; C23C 16/52

(52) U.S. Cl. CPC H01L 21/67196; C23C 16/4585; C23C 16/52; B25J 11/0095; H01L 21/67742; H01L 21/6719

(57) ABSTRACT

A vacuum carrier interface configured to interface with a transfer module, the vacuum carrier interface including an input interface configured to receive one or more substrates at atmospheric pressure; a substrate handling manifold configured to receive the one or more substrates from the input interface at atmospheric pressure and interface with the transfer module in a vacuum; an output interface configured to deliver one or more substrates to the transfer module from the substrate handling manifold; a vacuum manifold base plate and a lower pedestal, which are spaced apart, the vacuum manifold base plate and the lower pedestal forming a chamber between a lower surface of the vacuum manifold base plate and an upper surface of the lower pedestal; and an indexer configured to raise and lower the vacuum manifold base plate and the lower pedestal.

### FIELD

This disclosure relates to a vacuum carrier interface, and more particularly, a vacuum carrier interface, which can act as a vacuum indexer for a stack of substrate and a reduced volume airlock for processing of one or more substrates, for example, up to about 4 substrates.

### BACKGROUND

In the manufacture of semiconductor devices, process chambers are frequently interfaced to permit transfer of wafers or substrates, for example, between the interfaced chambers. The transfer can be performed via transfer modules that move the wafers, for example, through slots or ports that are provided in adjacent walls of the interfaced chambers. Transfer modules are generally used in conjunction with a variety of wafer processing modules (PMs), which may include semiconductor etching systems, material deposition systems, and flat panel display etching systems.

A processing tool, for example, which is commonly referred to as a process tool or other substrate production tool), can include an equipment front-end module (EFEM), and one or more process modules, each of the one or more process modules including a process chamber or other chamber types in which substrates are located, such as, for example, an in-situ metrology chamber. The process tool may include a substrate transfer section and a substrate process area, in which various processes are performed on a batch of substrates. The processes may include various types of, for example, substrate cleaning and wet-etch (e.g., chemical etch) steps known independently in the semiconductor and related art fields. Additionally, the process module is generally enclosed to reduce any particulate, organic, or other contamination of substrates within the process module and the process chamber, and to provide a vacuum environment, which can be required to enable, for example, plasma and metal film deposition. The enclosure minimizes a risk of hazardous interactions between an equipment operator and moving mechanisms and hazardous chemistries within the process module, thereby increasing safety of the operator.

In existing process chambers, a front opening unified pod (FOUP) can be used with equipment front end module (EFEM) to load substrates into the process chamber for processing. The FOUP is generally a particular type of enclosure designed to hold semiconductor substrates, for example, generally silicon wafers (Si) but may also include various other wafer types formed from elemental semiconductor materials such as germanium (Ge), or compound semiconductor materials such as gallium-arsenide (GaAs) or indium arsenide (InAs)). The FOUP can hold the substrates securely and safely in a controlled environment. A FOUP generally does not hold the substrates in a vacuum state.

In accordance with an exemplary embodiment, it would be desirable to have a vacuum carrier interface configured to index one or more substrates from a vacuum carrier in a vacuum condition, and wherein the vacuum carrier interface can also interface with, for example, a FOUP and/or a EFEM, such that substrates can be received at atmospheric pressure and processed via an airlock chamber in a vacuum transfer module (VTM) via a processing chamber to one or more processing modules.

### SUMMARY

In accordance with an exemplary embodiment, a vacuum carrier interface configured to interface with a transfer module, the vacuum carrier interface comprises: an input interface configured to receive one or more substrates at atmospheric pressure; a substrate handling manifold configured to receive the one or more substrates from the input interface at atmospheric pressure and interface with the transfer module in a vacuum; an output interface configured to deliver one or more substrates to the transfer module from the substrate handling manifold; a vacuum manifold base plate and a lower pedestal, which are spaced apart, the vacuum manifold base plate and the lower pedestal forming a chamber between a lower surface of the vacuum manifold base plate and an upper surface of the lower pedestal; and an indexer configured to raise and lower the vacuum manifold base plate and the lower pedestal, wherein the vacuum manifold base plate and the lower pedestal in a lowered position form a vacuum indexer above the vacuum manifold base plate, and the vacuum manifold base plate and the lower pedestal in a raised position form an airlock chamber between the lower surface of the vacuum manifold base plate and the upper surface of the lower pedestal when the vacuum manifold base plate and the lower pedestal is placed within the substrate handling manifold.

In accordance with an exemplary embodiment, a semiconductor processing system, comprises: a transfer module; one or more process modules, the one or more process modules configured to perform a semiconductor process on a substrate; and a vacuum carrier interface configured to interface with the transfer module, the vacuum carrier interface comprising: an input interface configured to receive one or more substrates at atmospheric pressure; a substrate handling manifold configured to receive the one or more substrates from the input interface at atmospheric pressure and interface with the transfer module in a vacuum; an output interface configured to deliver one or more substrates to the transfer module from the substrate handling manifold; a vacuum manifold base plate and a lower pedestal, which are spaced apart, the vacuum manifold base plate and the lower pedestal forming a chamber between a lower surface of the vacuum manifold base plate and an upper surface of the lower pedestal; and an indexer configured to raise and lower the vacuum manifold base plate and the lower pedestal, wherein the vacuum manifold base plate and the lower pedestal in a lowered position form a vacuum indexer above the vacuum manifold base plate, and the vacuum manifold base plate and the lower pedestal in a raised position form an airlock chamber between the lower surface of the vacuum manifold base plate and the upper surface of the lower pedestal when the vacuum manifold base plate and the lower pedestal is placed within the substrate handling manifold.

In accordance with an exemplary embodiment, a method of delivering a substrate to a transfer module in a vacuum, the method comprises: receiving one or more substrates at atmospheric pressure at an input interface of a vacuum carrier interface; processing the one or more substrates received from the input interface at atmospheric pressure in the vacuum carrier interface into a vacuum, the vacuum carrier interface comprises: an input interface configured to receive one or more substrates at atmospheric pressure; a substrate handling manifold configured to receive the one or more substrates from the input interface at atmospheric pressure and interface with the transfer module in a vacuum; an output interface configured to deliver one or more substrates to the transfer module from the substrate handling manifold; a vacuum manifold base plate and a lower pedestal, which are spaced apart, the vacuum manifold base plate and the lower pedestal forming a chamber between a lower surface of the vacuum manifold base plate and an upper surface of the lower pedestal; and an indexer configured to raise and lower the vacuum manifold base plate and the lower pedestal, wherein the vacuum manifold base plate and the lower pedestal in a lowered position form a vacuum indexer above the vacuum manifold base plate, and the vacuum manifold base plate and the lower pedestal in a raised position form an airlock chamber between the lower surface of the vacuum manifold base plate and the upper surface of the lower pedestal when the vacuum manifold base plate and the lower pedestal is placed within the substrate handling manifold; and delivering the one or more substrates in a vacuum to the transfer module via the output interface.

### BRIEF DESCRIPTION OF THE DRAWING FIGURES

FIG. 1 is a view of a semiconductor processing system in accordance with an exemplary embodiment.

FIG. 2 is a perspective view of the vacuum carrier interface with a vacuum carrier in accordance with an exemplary embodiment.

FIG. 3 is a cross-sectional view of the vacuum carrier interface of FIG. 2 in accordance with an exemplary embodiment.

FIG. 4 is a cross-sectional view of a portion of the vacuum carrier interface of FIG. 2 in accordance with an exemplary embodiment.

FIG. 5 is a cross-sectional view of the reduced capacity airlock chamber of the vacuum carrier interface of FIG. 2.

FIG. 6 is cross-sectional view of the reduced capacity airlock chamber of FIG. 5 in accordance with an exemplary embodiment.

### DETAILED DESCRIPTION

In the following detailed disclosure, exemplary embodiments are set forth in order to provide an understanding of the apparatus and methods disclosed herein. However, as will be apparent to those skilled in the art, that the exemplary embodiments may be practiced without these specific details or by using alternate elements or processes. In other instances, well-known processes, procedures, and/or components have not been described in detail so as not to unnecessarily obscure aspects of embodiments disclosed herein.

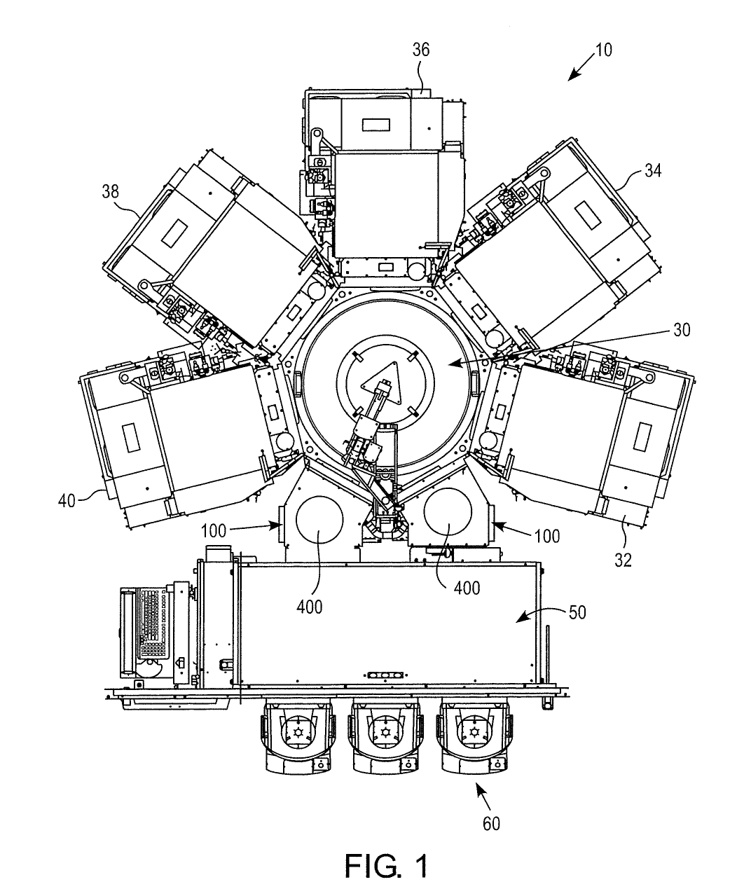

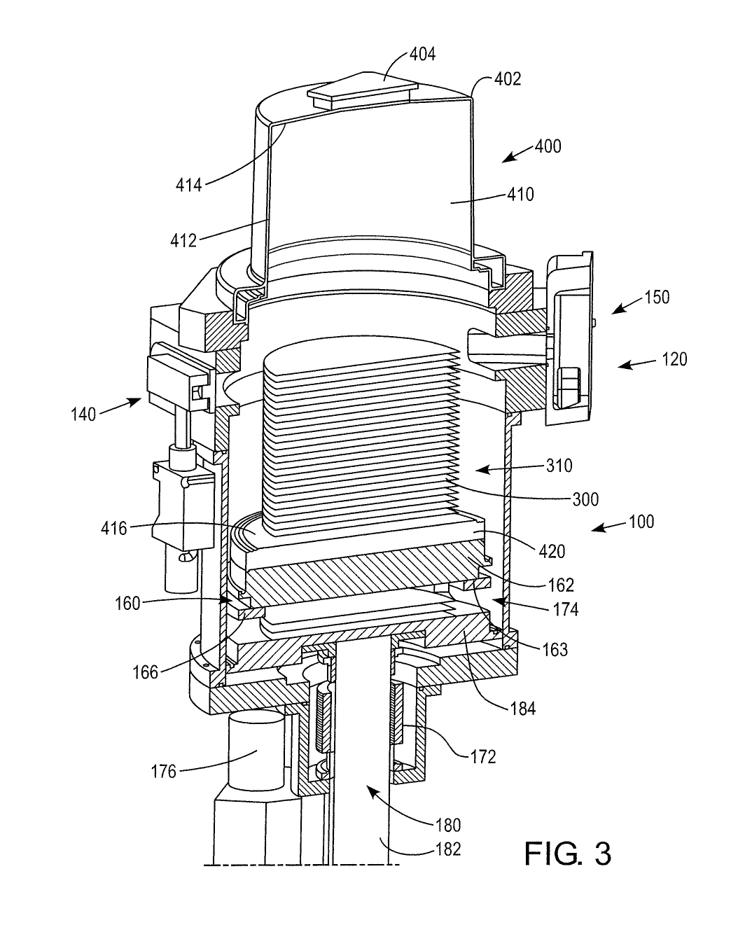

FIG. 1 is a view of a semiconductor processing system 10 in accordance with an exemplary embodiment. As shown in FIG. 1, the semiconductor processing system 10, which can include a transfer module 30 and one or more processing modules (PMs) 32, 34, 36, 38, 40, an optional EFEM 50, an optional FOUP 60, and one or more vacuum carrier interfaces 100. In addition, the system 10 can include a vacuum carrier 400. In accordance with an exemplary embodiment, a substrate 300 (FIG. 3) can be transferred within the semiconductor processing system 10 as shown in FIG. 1 by one or more robotic systems as known in the art, for example, as disclosed in commonly owned U.S. Pat. Nos. 8,282,698 and 8,562,272.

In accordance with an exemplary embodiment, the transfer of the substrates 300 (FIG. 3) can be performed via the transfer module 30 that moves the substrates 300, for example, through slots or ports, which are provided in adjacent walls of the interfaced chambers within the one or more processing modules 32, 34, 36, 38, 40, and the vacuum carrier interface 100. In accordance with an exemplary embodiment, the one or more processing modules 32, 34, 36, 38, 40 can include, for example, semiconductor etching systems, material deposition systems, and flat panel display etching systems.

In accordance with an exemplary embodiment, each of the one or more process modules 32, 34, 36, 38, 40 can include a process chamber or other chamber types in which substrates are located, such as, for example, an in-situ metrology chamber. The transfer module 30 may include a substrate transfer section, in which the substrates 300 can be transferred from the vacuum carrier interface 100 to one or more of the process modules 32, 34, 36, 38, 40, which processes the substrates 300. For example, the process modules 32, 34, 36, 38, 40 may include various types of, for example, substrate cleaning and wet-etch (e.g., chemical etch) steps known independently in the semiconductor and related art fields. In accordance with an exemplary embodiment, for example, the process modules 32, 34, 36, 38, 40 can include semiconductor manufacturing machines, semiconductor processing machines, semiconductor cleaning machines, semiconductor diagnostics support and maintenance machines, and replacement parts for use therewith in accordance, for example, with Lam Research's 2300® platform.

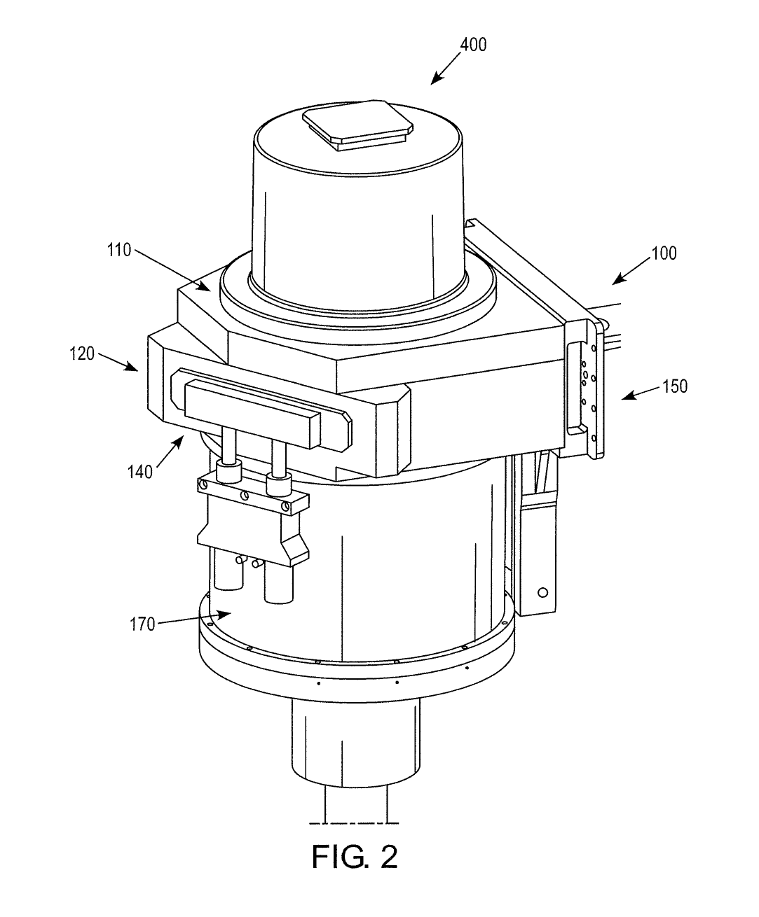

FIG. 2 is a perspective view of the vacuum carrier interface 100 with a vacuum carrier 400 in accordance with an exemplary embodiment. As shown in FIG. 2, in a first exemplary mode, the vacuum carrier interface 100 in combination with a vacuum carrier 400 can be an indexer for a stack of substrates 300 housed within the carrier 400. For example, as an indexer, the vacuum carrier interface 100 can be configured to be placed adjacent to the transfer module 30 to deliver substrates 300 from the vacuum carrier 400, which is received on an upper portion 110 of the vacuum carrier interface 100.

Alternatively, in a second exemplary mode, the vacuum carrier 100 can operate as a smaller airlock chamber 200 (FIG. 3) having a reduced airlock volume for processing one or more substrates, for example, two substrates. Thus, for example, in accordance with an exemplary embodiment, the vacuum carrier interface 100 can be configured to interface with, for example, a FOUP 60 and/or a EFEM 50, such that substrates 300 can be received at atmospheric pressure and processed via an airlock chamber to be transferred in a vacuum transfer mode (VTM) to the transfer module 30.

In accordance with an exemplary embodiment, the vacuum carrier interface 100 can include a substrate handling manifold 120 and an indexer manifold 170. In accordance with an exemplary embodiment, the substrate handling manifold 120 includes an airlock slot valve (or input interface) 140 and a vacuum transfer mode (VTM) slot valve (or output interface) 150. The airlock slot valve 140 is configured to receive substrates 300 from, for example, a wafer or substrate transport, such as a FOUP 60. In accordance with an exemplary embodiment, the substrates received via the airlock slot 140 can be at atmospheric pressure. The VTM slot valve 150 is configured to transfer substrates 300 in a vacuum to the transfer chamber 30.

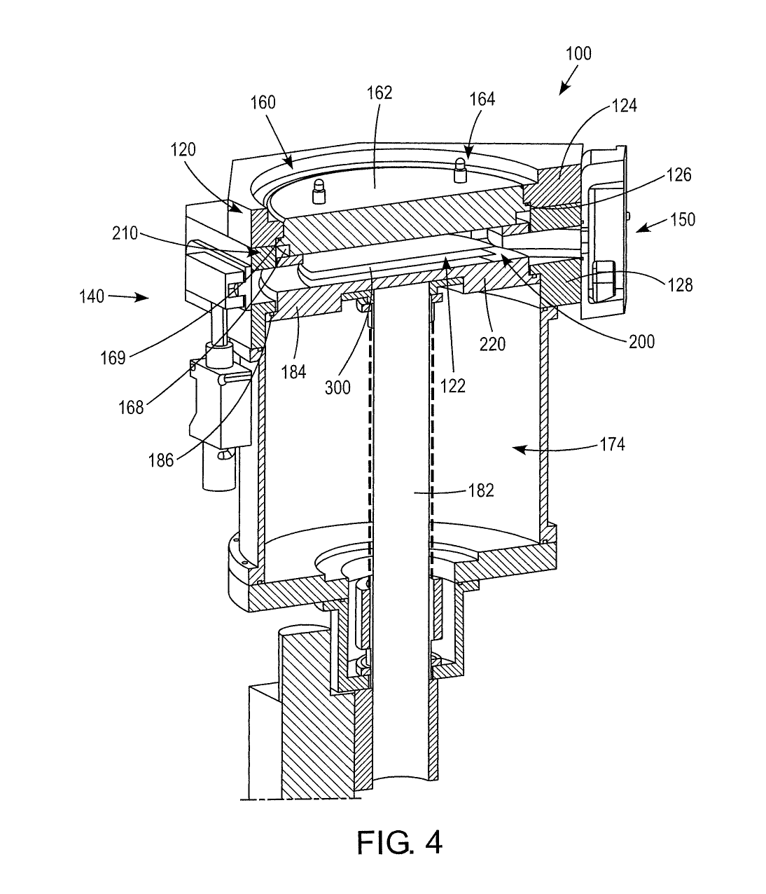

FIG. 3 is a cross-sectional view of the vacuum carrier interface 100 having a reduced airlock chamber 200 (FIG. 4) in accordance with an exemplary embodiment. As shown in FIG. 3, the vacuum carrier interface 100 includes the substrate handling manifold 120, the indexer manifold 170, and an indexer 180.

In accordance with an exemplary embodiment, the vacuum carrier interface 100 can include a vacuum manifold base plate 160, which includes a vacuum chamber interface plate 162 having one or more kinematic pins 164, and an annular ring 166 on an outer lower edge 163 of the vacuum chamber interface plate 162. The vacuum chamber interface plate 162 and the kinematic pins 164 are configured to receive a lower portion, for example, a vacuum carrier base plate 420 of a vacuum carrier 400. For example, the vacuum chamber interface plate 162 can include 3 (three) kinematic pins 164, which are equally spaced around an upper surface of the vacuum chamber interface plate 162. In accordance with an exemplary embodiment, the vacuum chamber interface plate 162, the one or more kinematic pins 164, and the annular ring 166 can be a single unit.

In accordance with an exemplary embodiment, the indexer manifold 170 can include an indexer bellows manifold (or bellows) 172 for maintaining a vacuum within the vacuum carrier interface 100, and a lower chamber 174. In accordance with an exemplary embodiment, the indexer bellows manifold 172 is configured to maintain a vacuum condition within the upper chamber 110, the lower chamber 174, and/or the airlock chamber 200. Bellows may also maintain a pressurized condition in the lower chamber 174 when the airlock chamber 200 is being used to transfer wafers.

In accordance with an exemplary embodiment, for example, the vacuum carrier interface 100 can be configured to include a separate vents and pump ports (not shown) for the upper carrier chamber 110, the lower chamber 174, and the airlock chamber 200, which can communicate with the indexer bellows manifold 172 to create a vacuum environment in accordance with a desired operating condition of the vacuum carrier interface 100. The vacuum carrier interface 100 also includes an indexer driver 176, which controls the raising and lowering of the indexer 180. In accordance with an exemplary embodiment, the indexer 180 is housed in the indexer manifold 170. The indexer 180 can include an indexer post 182 and a lower pedestal or platform 184.

In accordance with an exemplary embodiment, the substrate handling manifold 120 is configured to receive substrates 300 via the airlock slot valve 140 and depending on the positioning of the indexer 180, the vacuum carrier interface 100 can act as an indexer in a lowered position, or alternatively, the vacuum carrier interface 100 can be configured to operate as a reduced airlock chamber 200 having a smaller chamber capacity in a raised position, for example, for handling two substrates.

In accordance with an exemplary embodiment, the reduced airlock chamber 200 of the vacuum carrier interface 100 is configured to receive, for example, two spaced apart substrates 300 at atmospheric pressure via the airlock slot valve 140, and provide the substrates 300 to the transfer module 30 in a vacuum transfer mode (VTM) via the VTM slot valve 150. In accordance with an exemplary embodiment, the substrates 300 can be transferred from within the reduced airlock chamber 200 to the airlock slot valve 140 and/or the VTM slot valve by one or more robotic systems as known in the art, for example, as disclosed in commonly owned U.S. Pat. No. 8,562,272.

In accordance with an exemplary embodiment, by providing a reduced airlock chamber 200 in combination with a vacuum carrier, the vacuum carrier interface 100 can coexist with conventional airlocks and interface ports, can act as a bridging tool for users who are developing vacuum carrier integration into substrate processing, and increased throughput during use as conventional airlock by providing a smaller or reduced volume to place in a vacuum as compared to a single vacuum chamber or manifold, which is configured to hold a stack of spaced apart substrates, for example, 20 to 25 substrates.

The vacuum carrier 400 can include, for example, an annular housing 412 having an upper vacuum chamber 410 formed therein, which is configured to surround a stack of spaced apart substrates 310 in a vacuum, and which are positioned on or above a vacuum carrier base plate 420. The upper vacuum chamber 410 can be defined as an inner chamber between the annular housing 412, a chamber top 414, and an upper surface 416 of the vacuum carrier base plate 420. The vacuum carrier 400 can also include an atmospheric port 404 on the chamber top 414 of the vacuum carrier 400.

In accordance with an exemplary embodiment, the term “substrate” 300 has been chosen as a convenient term referring to any of various substrate types used in the semiconductor and allied industries. Substrate 300 can include silicon wafers, compound wafers, thin film head assemblies, polyethylene-terephthalate (PET) films, photomask blanks and reticles, or numerous other types of substrates known in the art. In accordance with an exemplary embodiment, for example, the substrates 300 can have an outer diameter of about 200 mm to about 450 mm.

In accordance with an exemplary embodiment, the stack of substrates 310 can be, for example, a stack of 25 (twenty-five) spaced apart substrates 300, and wherein the upper vacuum manifold or chamber 110 includes a substrate slot, for example, a pair of opposing grooves, configured to hold each of the substrates 300 before and/or after processing.

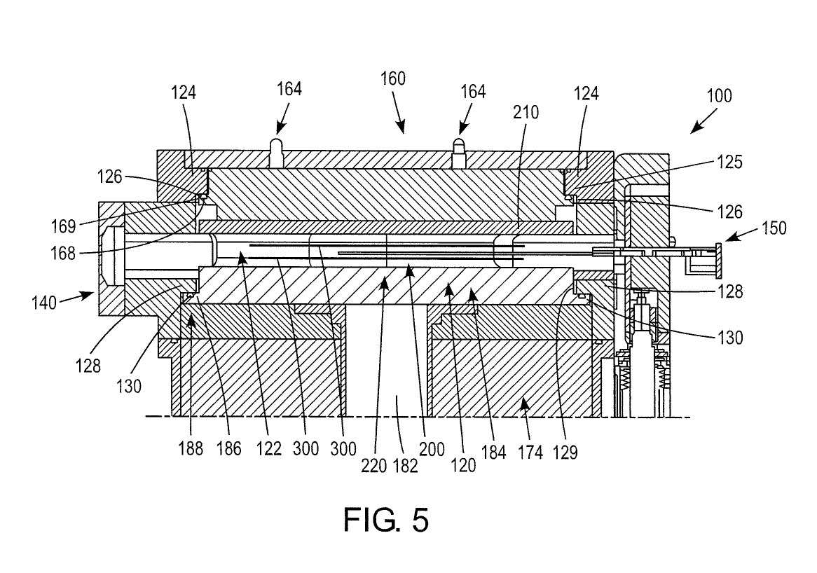

FIGS. 4 and 5 are cross-sectional views of a portion of the vacuum carrier interface 100 of FIG. 2 with the vacuum manifold base plate 160 in a raised position forming the airlock chamber 200. As shown in FIGS. 4 and 5, the substrate handling manifold 120 can include, for example, an annular chamber 122. The annular chamber 122 can include an upper annular flange 124 having an upper annular seal 126 on a lower edge 125 of the upper annular flange 124. The annular chamber 122 also can include a lower annular flange 128 having a lower annular seal 130 on a lower edge 129 of the lower annular flange 128. In accordance with an exemplary embodiment, the upper annular flange 124 and the upper annular seal 126 are configured to seal against an upper annular sealing flange 168 on an outer edge 169 of the vacuum chamber interface plate 162 forming an upper wall 210 of the airlock chamber 200.

In accordance with an exemplary embodiment, the lower pedestal or platform 184 includes a lower annular sealing flange 186 on outer edge 188 of the pedestal or platform 184. The lower annular sealing flange 186 is configured to engage with the lower annular seal 130 forming a lower wall 220 of the airlock chamber 200 when the indexer post 182 is in a raised position. In accordance with an exemplary embodiment, the upper annular seal 126 and the lower annular seal 130 can be O-rings. In accordance with an exemplary embodiment, the upper and the lower annular seals (or O-rings), for example, can be made of a silicone based elastomeric material, which can produce a gas tight (vacuum or pressurized) seal.

In accordance with an exemplary embodiment, upon raising the indexer 180, the airlock chamber 200 is formed between the upper and the lower walls 210, 220. The upper wall 210 is formed by sealing the upper annual sealing flange 168 of the vacuum chamber interface plate 162 against the upper annular seal 126. The lower wall 220 is formed by the lower pedestal or platform 184, which includes the lower annular sealing flange 186 on the outer edge 188 of the pedestal or platform 184, which is configured to engage the lower annular seal 130 on the lower edge of the lower annular flange 128.

In accordance with an exemplary embodiment, for example, when the vacuum carrier interface 100 is in a raised position having a reduced airlock chamber 200, during receipt of the one or more substrates 300 via the airlock slot valve (or input interface) 140, the lower chamber 174 can be pressurized to counter the atmospheric loading as well as adding an additional compression force to the annular seals 126, 130.

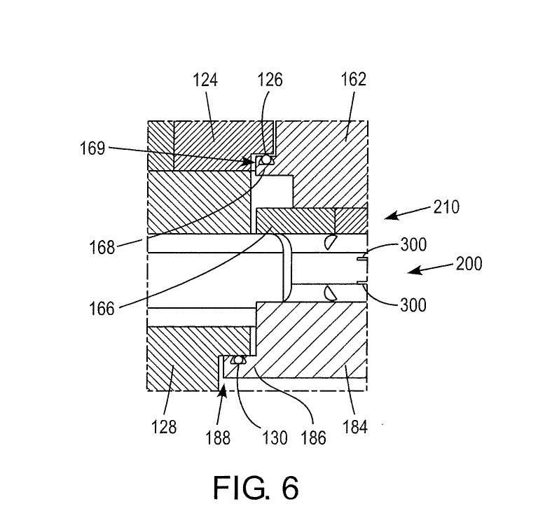

FIG. 6 is cross-sectional view of the airlock chamber of FIG. 5 in accordance with an exemplary embodiment. As shown in FIG. 6, the upper annular flange 124 and the upper annular seal 126 are configured to seal against the sealing flange 168 on an outer edge 169 of the vacuum chamber interface plate 162 forming an upper wall 210 of the reduced airlock chamber 200. In addition, the lower pedestal or platform 184 includes the lower annular sealing flange 186 on the outer edge 188 of the pedestal or platform 184. The lower annular sealing flange 186 is configured to engage with the lower annular seal 130 forming a lower wall 220 of the reduced airlock chamber 200 when the indexer post 182 is in a raised position.

Moreover, when the words “generally”, “relatively”, and “substantially” are used in connection with geometric shapes, it is intended that precision of the geometric shape is not required but that latitude for the shape is within the scope of the disclosure. When used with geometric terms, the words “generally”, “relatively”, and “substantially” are intended to encompass not only features, which meet the strict definitions, but also features, which fairly approximate the strict definitions.

While the plasma processing apparatus including an isothermal deposition chamber has been described in detail with reference to specific embodiments thereof, it will be apparent to those skilled in the art that various changes and modifications can be made, and equivalents employed, without departing from the scope of the appended claims.

What is claimed is:

1. A vacuum carrier interface configured to interface with a transfer module, the vacuum carrier interface comprising:
an input interface configured to receive one or more substrates at atmospheric pressure;
a substrate handling manifold configured to receive the one or more substrates from the input interface at atmospheric pressure and interface with the transfer module in a vacuum;
an output interface configured to deliver one or more substrates to the transfer module from the substrate handling manifold;
a vacuum manifold base plate and a lower pedestal, which are spaced apart, the vacuum manifold base plate and the lower pedestal forming a chamber between a lower surface of the vacuum manifold base plate and an upper surface of the lower pedestal; and
an indexer configured to raise and lower the vacuum manifold base plate and the lower pedestal, wherein the vacuum manifold base plate and the lower pedestal in a lowered position form a vacuum indexer above the vacuum manifold base plate, and the vacuum manifold base plate and the lower pedestal in a raised position form an airlock chamber between the lower surface of the vacuum manifold base plate and the upper surface of the lower pedestal when the vacuum manifold base plate and the lower pedestal is placed within the substrate handling manifold.

2. The vacuum carrier interface of claim 1, wherein the substrate handling manifold includes an annular chamber in communication with the input interface and the output interface, the annular chamber including an upper annular flange having an upper annular seal on a lower edge of the upper annular flange, and a lower annular flange having a lower annular seal on a lower edge of the lower annular flange.

3. The vacuum carrier interface of claim 2, wherein
the upper annular sealing flange is configured to seal against an upper annular sealing flange on an outer edge of the vacuum manifold base plate, which forms an upper wall of the airlock chamber; and
the lower annular sealing flange is configured to seal against a lower annular sealing flange on outer edge of the lower pedestal, which forms a lower wall of the airlock chamber.

4. The vacuum carrier interface of claim 3, wherein the upper annular seal and the lower annular seal are O-rings.

5. The vacuum carrier interface of claim 2, wherein the vacuum manifold base plate includes one or more pins configured to receive a base of a vacuum carrier.

6. The vacuum carrier interface of claim 5, wherein the vacuum manifold base plate, the pins and the annular ring are a single unit.

7. The vacuum carrier interface of claim 1, comprising:
an indexer manifold, the indexer manifold including bellows for creating a vacuum within the carrier;
a lower chamber located beneath a lower surface of the lower pedestal; and
an indexer driver, which controls the raising and lowering of the indexer.

8. The vacuum carrier interface of claim 1, comprising:
a vacuum carrier including an annular housing configured to surround a stack of spaced apart substrates, and a vacuum carrier base plate, which is received on one or more pins on the vacuum manifold base plate.

9. The vacuum carrier interface of claim 8, wherein the vacuum carrier is configured to hold up to about 20 to 25 substrates and the airlock chamber is configured to hold up to about 4 substrates.

10. The vacuum carrier interface of claim 1, wherein the input interface is configured to interface with an equipment front-end module (EFEM) and/or a substrate carrier at atmospheric pressure.

11. The vacuum carrier interface of claim 10, wherein the substrate carrier at atmospheric pressure is a front opening unified pod (FOUP).

12. A semiconductor processing system, comprising:
a transfer module;
one or more process modules, the one or more process modules configured to perform a semiconductor process on a substrate; and
a vacuum carrier interface configured to interface with the transfer module, the vacuum carrier interface comprising:
an input interface configured to receive one or more substrates at atmospheric pressure;
a substrate handling manifold configured to receive the one or more substrates from the input interface at atmospheric pressure and interface with the transfer module in a vacuum;
an output interface configured to deliver one or more substrates to the transfer module from the substrate handling manifold;
a vacuum manifold base plate and a lower pedestal, which are spaced apart, the vacuum manifold base plate and the lower pedestal forming a chamber between a lower surface of the vacuum manifold base plate and an upper surface of the lower pedestal; and
an indexer configured to raise and lower the vacuum manifold base plate and the lower pedestal, wherein the vacuum manifold base plate and the lower pedestal in a lowered position form a vacuum indexer above the vacuum manifold base plate, and the vacuum manifold base plate and the lower pedestal in a raised position form an airlock chamber between the lower surface of the vacuum manifold base plate and the upper surface of the lower pedestal when the vacuum manifold base plate and the lower pedestal is placed within the substrate handling manifold.

13. The system of claim 12, wherein the substrate handling manifold includes an annular chamber in communication with the input interface and the output interface, the annular chamber including an upper annular flange having an upper annular seal on a lower edge of the upper annular flange, and a lower annular flange having a lower annular seal on a lower edge of the lower annular flange.

14. The system of claim 13, wherein
the upper annular sealing flange is configured to seal against an upper annular sealing flange on an outer edge of the vacuum manifold base, which forms an upper wall of the airlock chamber; and
the lower annular sealing flange is configured to seal against a lower annular sealing flange on outer edge of the lower pedestal, which forms a lower wall of the airlock chamber.

15. The system of claim 14, comprising:
a transfer module configured transfer a substrate from the vacuum carrier interface to one or more of the process modules in a vacuum.

16. The system of claim 14, comprising:
an equipment front-end module (EFEM), which is configured to interface with the input interface of the vacuum carrier interface.

17. The system of claim 14, comprising:
an atmospheric pressure substrate carrier, which is configured to interface with the input interface of the vacuum carrier interface.

18. A method of delivering a substrate to a process module in a vacuum, the method comprising:
receiving one or more substrates at atmospheric pressure at an input interface of a vacuum carrier interface;
processing the one or more substrates received from the input interface at atmospheric pressure in the vacuum carrier interface into a vacuum, the vacuum carrier interface comprising:
an input interface configured to receive one or more substrates at atmospheric pressure;
a substrate handling manifold configured to receive the one or more substrates from the input interface at atmospheric pressure and interface with a transfer module in a vacuum;
an output interface configured to deliver one or more substrates to the transfer module from the substrate handling manifold;
a vacuum manifold base plate and a lower pedestal, which are spaced apart, the vacuum manifold base plate and the lower pedestal forming a chamber between a lower surface of the vacuum manifold base plate and an upper surface of the lower pedestal; and
an indexer configured to raise and lower the vacuum manifold base plate and the lower pedestal, wherein the vacuum manifold base plate and the lower pedestal in a lowered position form a vacuum indexer above the vacuum manifold base plate, and the vacuum manifold base plate and the lower pedestal in a raised position form an airlock chamber between the lower surface of the vacuum manifold base plate and the upper surface of the lower pedestal when the vacuum manifold base plate and the lower pedestal is placed within the substrate handling manifold; and
delivering the one or more substrates in a vacuum to the transfer module via the output interface.
